(19) United States
(12) Patent Application Publication
(10) Pub. No.: US 2026/0148946 A1
(43) Pub. Date: May 28, 2026

(54) PLASMA MONITORING APPARATUS

(71) Applicant: Samsung Electronics Co., Ltd., Suwon-si (KR)

(72) Inventors: Taehyun Kim, Suwon-si (KR); Daewon Kang, Suwon-si (KR); Chansoo Kang, Suwon-si (KR); Jitae Park, Suwon-si (KR); Sejin Oh, Suwon-si (KR); Sungho Jang, Suwon-si (KR)

(21) Appl. No.: 19/305,522

(22) Filed: Aug. 20, 2025

(30) Foreign Application Priority Data
Nov. 26, 2024 (KR) 10-2024-0171469

(51) Int. Cl. H01J 37/32

(52) U.S. Cl. CPC H01J 37/32935

(57) ABSTRACT

An example plasma monitoring apparatus includes a monitoring structure fixed to a sidewall of a plasma chamber housing such that the monitoring structure is in contact with a viewport located in the sidewall of the plasma chamber housing, a cylindrical lens provided inside the monitoring structure and located at a front end of the monitoring structure, the cylindrical lens configured to receive a plurality of rays of plasma emission light emitted from a plasma space of interest inside the plasma chamber housing, and a plasma detector provided inside the monitoring structure and located at a rear end of the monitoring structure, the plasma detector configured to detect the plurality of rays of plasma emission light transmitted through the cylindrical lens. The cylindrical lens includes a side surface in a form of a circumferential surface convex or concave in a second horizontal direction.

### CROSS-REFERENCE TO RELATED APPLICATION

This application claims priority under 35 U.S.C. § 119 to Korean Patent Application No. 10-2024-0171469, filed on Nov. 26, 2024, in the Korean Intellectual Property Office, the disclosure of which is incorporated by reference herein in its entirety.

### BACKGROUND

Due to an increase in difficulty of processes using plasma, techniques for monitoring states of the plasma have been increasingly important in order to precisely control plasma treatment processes. Therefore, research continues on techniques for monitoring the states of the plasma used in the plasma treatment process.

Research has been conducted on techniques for estimating three-dimensional (3D) spatial distribution of plasma emission light on the basis of volumetric tomography methods.

### SUMMARY

The present disclosure relates to a plasma monitoring apparatus capable of estimating 3D spatial distribution of plasma emission light.

However, the objects of the present disclosure are not limited to the aforementioned object, but other objects not described herein will be clearly understood by those skilled in the art from the following description.

In some implementations, a plasma monitoring apparatus includes a monitoring structure fixed to a sidewall of a plasma chamber housing such that the monitoring structure is in contact with a viewport located in the sidewall of the plasma chamber housing, a cylindrical lens provided inside the monitoring structure and located at a front end of the monitoring structure, the cylindrical lens configured to receive a plurality of rays of plasma emission light emitted from a plasma space of interest inside the plasma chamber housing, and a plasma detector provided inside the monitoring structure and located at a rear end of the monitoring structure, the plasma detector configured to detect the plurality of rays of plasma emission light transmitted through the cylindrical lens, wherein the cylindrical lens includes a side surface in a form of a circumferential surface convex or concave in a second horizontal direction, the side surface of the cylindrical lens faces the plasma detector and is oriented perpendicular to a horizontal direction, the plasma space of interest includes a space, having a vertical level equal to a vertical level of the viewport, in an inner space of the plasma chamber housing, and the second horizontal direction is defined as a direction from a center of the plasma space of interest toward the viewport.

In some implementations, a plasma monitoring apparatus includes a monitoring structure fixed to a sidewall of a plasma chamber housing such that the monitoring structure is in contact with a viewport located in the sidewall of the plasma chamber housing, a lens unit located inside the monitoring structure and receiving a plurality of rays of plasma emission light having a wide field of view, the lens unit configured to output the received plurality of rays of plasma emission light in collimation in a first horizontal direction and to output the received plurality of rays of plasma emission light telecentrically in a vertical direction, a plasma detector configured to obtain a 2D image based on the plurality of rays of plasma emission light output from the lens unit, and a controller configured to estimate, based on the 2D image and a weight matrix, a 3D spatial distribution of the plurality of rays of plasma emission light within a plasma space of interest, wherein the 2D image includes a plurality of pixels arranged in n1 rows and n2 columns, the weight matrix includes a plurality of weight coefficients configured to respectively associate a plurality of vertical levels in the plasma space of interest with the n1 rows in a one-to-one correspondence, the plasma space of interest includes a space, having a vertical level equal to a vertical level of the viewport, in an inner space of the plasma chamber housing, and the first horizontal direction is perpendicular to a second horizontal direction from a center of the plasma space of interest toward the viewport.

In some implementations, a plasma monitoring apparatus includes a plasma chamber housing, a viewport located in a sidewall of the plasma chamber housing, a monitoring structure in contact with the viewport and fixed to the sidewall, in which the viewport is located, of the plasma chamber housing, at least one cylindrical lens provided inside the monitoring structure and located at a front end of the monitoring structure, the at least one cylindrical lens configured to receive a plurality of rays of plasma emission light emitted from a plasma space of interest, at least one circular lens provided inside the monitoring structure and located behind the at least one cylindrical lens, the at least one circular lens configured to collect the plurality of rays of plasma emission light at a preset magnification, and a plasma detector provided inside the monitoring structure and located behind the at least one circular lens, the plasma detector configured to receive the plurality of rays of plasma emission light to obtain a 2D image, wherein the at least one cylindrical lens is configured to receive the plurality of rays of plasma emission light having a wide field of view, the at least one cylindrical lens being configured to output the received plurality of rays of plasma emission light in collimation in a first horizontal direction and to output the received plurality of rays of plasma emission light telecentrically in a vertical direction, the plasma space of interest includes a space, having a vertical level equal to a vertical level of the viewport, in an inner space of the plasma chamber housing, the preset magnification is determined based on a size of a 2D pixel array in the plasma detector, and the first horizontal direction is perpendicular to a second horizontal direction from a center of the plasma space of interest toward the viewport.

### BRIEF DESCRIPTION OF THE DRAWINGS

Implementations will be more clearly understood from the following detailed description taken in conjunction with the accompanying drawings.

FIG. 1 is a cross-sectional view of an example of a plasma monitoring apparatus.

FIG. 2 is an example schematic cross-sectional view of the plasma monitoring apparatus of FIG. 1, taken along line A-A′ of FIG. 1.

FIG. 3 is a perspective view of an example of a cylindrical lens.

FIG. 4 is a perspective view schematically illustrating an example of a method of estimating a 3D spatial distribution of plasma emission light in a plasma monitoring apparatus.

FIG. 5 is an example schematic cross-sectional view of a plurality of voxels and a 2D pixel array.

FIG. 6 is a cross-sectional view of an example of a plasma monitoring apparatus.

FIG. 7 is a cross-sectional view of an example of a plasma monitoring apparatus.

FIG. 8 is a table schematically showing the effect of an example of a plasma monitoring apparatus.

### DETAILED DESCRIPTION

Hereinafter, implementations are described in detail with reference to the accompanying drawings. The same reference numerals are given to the same elements in the drawings, and repeated descriptions thereof are omitted.

As used herein, a horizontal direction may include a first horizontal direction (an X direction) and a second horizontal direction (a Y direction) that intersect each other. A direction intersecting both the first horizontal direction (the X direction) and the second horizontal direction (the Y direction) may be referred to as a vertical direction (a Z direction). As used herein, the vertical level may be referred to as a height level of any component in the vertical direction (the Z direction).

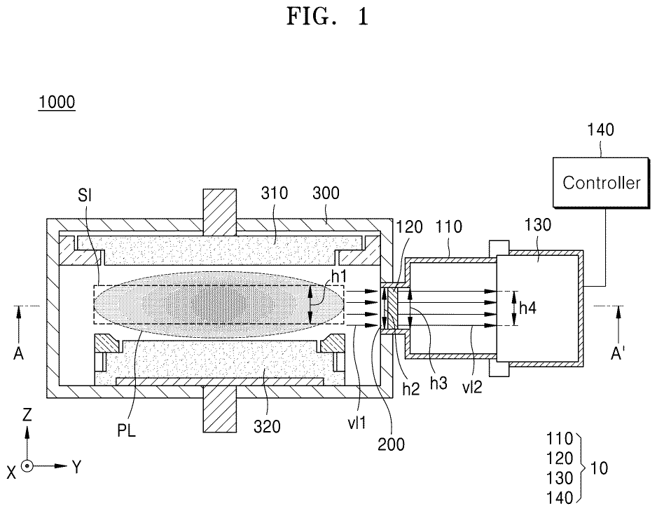

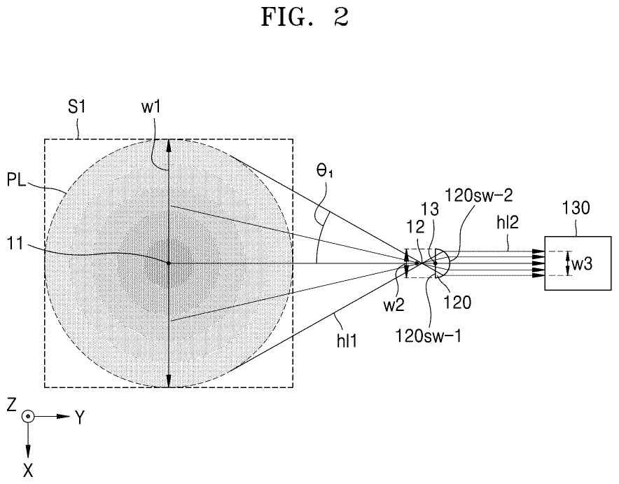

FIG. 1 is a cross-sectional view of an example of a plasma monitoring apparatus 1000. FIG. 2 is an example schematic cross-sectional view of the plasma monitoring apparatus 1000 of FIG. 1, taken along line A-A′ of FIG. 1.

Referring to FIG. 1, the plasma monitoring apparatus 1000 may include a plasma monitoring unit 10, a viewport 200, a plasma chamber housing 300, an upper electrode 310, and a lower electrode 320.

The plasma monitoring unit 10 may include a monitoring structure 110, a cylindrical lens 120, a plasma detector 130, and a controller 140.

The monitoring structure 110 may constitute the exterior of the plasma monitoring unit 10. The monitoring structure 110 may have a cylindrical shape and include a certain inner space. The monitoring structure 110 may be fixed to a sidewall of the plasma chamber housing 300 so that the monitoring structure 110 is in contact with the viewport 200.

The monitoring structure 110 may include a heat-resistant material that is not deformed by high-temperature heat radiated from the plasma chamber housing 300 and prevents heat from being transferred to the inner space of the monitoring structure 110. Also, the monitoring structure 110 may include a material having excellent wear and corrosion resistant characteristics. For example, the monitoring structure 110 may be formed as an aluminum block and include ceramic, quartz, or the like.

The front end of the monitoring structure 110 may be coupled and fixed to a sidewall of the plasma chamber housing 300. The monitoring structure 110 may include a coupling member capable of forming coupling to the sidewall of the plasma chamber housing 300. The coupling member may include various other members, such as a bolt/nut and an O-ring.

A lens unit may be located inside the monitoring structure 110. The lens unit may include a single lens or may include a plurality of lenses. In the description with reference to FIGS. 1 and 2, only the case in which the lens unit includes a single cylindrical lens 120 is described as an example.

The cylindrical lens 120 may be located inside the monitoring structure 110. Specifically, the cylindrical lens 120 may be located at the front end of the monitoring structure 110 and thus adjacent to the viewport 200. For example, the distance between the cylindrical lens 120 and the viewport 200 in the second horizontal direction (the Y-axis direction) may be equal to or less than 10 mm.

As the cylindrical lens 120 is adjacent to the viewport 200, the cylindrical lens 120 may collect a plurality of rays of plasma emission light having a wide field of view (FOV) in the first horizontal direction (the X-axis direction). Also, the cylindrical lens 120 may telecentrically output the plurality of rays of input plasma emission light in the vertical direction (the Z-axis direction).

As used herein, the plurality of rays of plasma emission light may represent light emitted from plasma present in a plasma space of interest SI. Also, the plurality of rays of plasma emission light may represent a plurality of rays of light input to the plasma monitoring unit 10 via the viewport 200. For example, the plurality of rays of plasma emission light may include ultraviolet light, X-rays, and the like that are generated by changes in energy levels of electrons.

Also, in some implementations, the plasma space of interest SI may represent a space, including plasma PL being monitored, among the entire inner space of the plasma chamber housing 300. For example, as illustrated in FIG. 1, the plasma space of interest SI may represent a space, having the same vertical level as the viewport 200, among the entire inner space of the plasma chamber housing 300. Specifically, the plasma space of interest SI may have a wide spatial distribution in the horizontal direction and only a spatial distribution having the same vertical level as the viewport 200 in the vertical direction.

Referring to FIG. 1, the cylindrical lens 120 may transmit a plurality of rays of plasma emission light in the vertical direction without refraction. In the description of the lateral cross-sectional view of FIG. 1, a case is illustrated, for convenience of description, in which a plurality of rays of vertical emission light vl1 are emitted from the plasma space of interest SI.

In some implementations, the plurality of rays of vertical emission light vl1 may represent a plurality of rays of plasma emission light emitted from the identical horizontal spaces. Also, the identical horizontal spaces may include a plurality of voxels having identical horizontal coordinates inside the plasma space of interest SI.

For example, the plasma space of interest SI may be divided into voxels having a cuboid shape that are arranged in 4 layers, 5 rows, and 5 columns. Here, the “layers” dividing the plasma space of interest SI may represent a plurality of vertical levels that are spaced apart from each other at regular intervals in the plasma space of interest SI. In this case, the plurality of rays of vertical emission light vl1 may include first layer-plasma emission light, second layer-plasma emission light, third layer-plasma emission light, and fourth layer-plasma emission light. Here, the first layer-plasma emission light to the fourth layer-plasma emission light may represent plasma emission light emitted from 25 voxels arranged in the identical horizontal spaces in the first to fourth layers, respectively.

As illustrated in FIG. 1, a vertical thickness h3 of the cylindrical lens 120 may be equal to a vertical height h1 of the plasma space of interest SI. Also, a vertical thickness h2 of the viewport 200 may be substantially the same as the vertical thickness h3 of the cylindrical lens 120.

Accordingly, a plurality of vertical light paths may be parallel to each other and also parallel to the second horizontal direction. Here, the plurality of vertical light paths may respectively represent light paths along which the plurality of rays of vertical emission light vl1 are incident toward the cylindrical lens 120.

A plurality of rays of vertical transmission light vl2 may travel parallel to the second horizontal direction and may be input to the plasma detector 130. The plurality of rays of vertical transmission light vl2 may represent the plurality of rays of vertical emission light vl1 that have transmitted through the cylindrical lens 120. That is, the cylindrical lens 120 may telecentrically transmit the plurality of rays of vertical emission light vl1 and deliver the same to the plasma detector 130. Here, the second horizontal direction may be the same as a direction from the center of the plasma space of interest SI toward the viewport 200.

As illustrated in FIG. 1, a vertical thickness h4 of the plurality of rays of vertical transmission light vl2 arriving at a detection surface of the plasma detector 130 may be equal to the vertical thickness h3 of the cylindrical lens 120.

The cylindrical lens 120 may collimate the plurality of rays of plasma emission light in the first horizontal direction. FIG. 2 is a top-view of a plasma monitoring apparatus 1000 taken along line A-A′ of FIG. 1. In the description with reference to FIG. 2, a case is illustrated, for convenience of description, in which a plurality of rays of horizontal emission light hl1 are emitted from the plasma space of interest SI.

In some implementations, the plurality of rays of horizontal emission light hl1 may represent a plurality of rays of plasma emission light emitted from the identical vertical spaces. Also, the identical vertical spaces may include a plurality of voxels having identical vertical coordinates inside the plasma space of interest SI.

For example, the plasma space of interest SI may be divided into voxels having a cuboid shape that are arranged in 4 layers, 5 rows, and 5 columns. In this case, the plurality of rays of horizontal emission light hl1 may include plasma emission light emitted from 25 voxels included in a single layer. Also, the plurality of rays of horizontal emission light hl1 may include a plurality of rays of plasma emission light that are inclined at different angles relative to the second horizontal direction.

As illustrated in FIG. 2, the plurality of rays of horizontal emission light hl1 may include a plurality of rays of plasma emission light that are respectively transmitted along optical paths present in an angular range from an angle inclined by a first angle θ₁ clockwise relative to the second horizontal direction to an angle inclined by the first angle θ₁ counterclockwise relative to the second horizontal direction.

Here, the first angle θ₁ may represent the FOV of the cylindrical lens 120 in the first horizontal direction. The first angle θ₁ may be determined based on a focal length f_{c} of the cylindrical lens 120 and a width w2 of the cylindrical lens 120 in the first horizontal direction. Here, the focal length fₑ refers to a distance between a lens center 13 and a focal point 12 of the cylindrical lens 120. For example, as illustrated in FIG. 2, when a second side surface 120sw-2 of the cylindrical lens 120 is formed as a circumferential surface, the first angle θ₁ may be tan⁻¹ (w2/2f_{c}) (θ₁=tan⁻¹(w2/2f_{c})). For example, the first angle θ₁ may be about 70 degrees to about 80 degrees.

As illustrated in FIG. 2, the width w2 of the cylindrical lens 120 in the first horizontal direction may be less than a width w1 of the plasma space of interest SI in the first horizontal direction. Also, a lens center 13 of the cylindrical lens 120 may be aligned with a center 11 of the plasma space of interest SI. In other words, the lens center 13 and the center 11 of the plasma space of interest SI may have the same first horizontal coordinate (the X coordinate) and the same vertical coordinate (the Z coordinate).

The plurality of rays of horizontal emission light hl1 may be inclined at different angles relative to the second horizontal direction and incident on the cylindrical lens 120. The cylindrical lens 120 may collimate and transmit the plurality of rays of horizontal emission light hl1. A plurality of rays of horizontal transmission light hl2 collimated by passing through the cylindrical lens 120 may be input to the plasma detector 130. As shown in FIG. 2, a width w3 of the plurality of rays of horizontal transmission light hl2 in the first horizontal direction arriving at the detection surface of the plasma detector 130 may be substantially the same as the width w2 of the cylindrical lens 120 in the first horizontal direction.

While it has been described above that the plurality of rays of plasma emission light are divided into the plurality of rays of vertical emission light vl1 and the plurality of rays of horizontal emission light hl1, this is only intended to separately illustrate the vertical direction/the horizontal direction so as to clearly describe the functions of the cylindrical lens 120. Actually, it is also noted that the plurality of rays of plasma emission light may include any light that propagates in various directions.

The plasma detector 130 may be located at a rear end of the monitoring structure 110 inside the monitoring structure 110. The plasma detector 130 may detect the plurality of rays of plasma emission light that have transmitted through the lens unit. In other words, the plasma detector 130 may obtain a 2D image on the basis of the plurality of rays of plasma emission light transmitted through the lens unit.

The plasma detector 130 may include a 2D pixel array for receiving the plurality of rays of plasma emission light and an electrical conversion circuit. The electrical conversion circuit may convert a light quantity of the plasma emission light sensed in each of a plurality of pixels included in the 2D pixel array, into an electrical signal and output the same.

Here, the 2D pixel array of the plasma detector 130 may be oriented perpendicular to the horizontal direction. In addition, the 2D pixel array may include a plurality of pixels that are arranged in n1 rows and n2 columns. The n2 pixels in each of the n1 rows may be arranged in the first horizontal direction (the x-axis direction) and the n1 pixels in each of the n2 columns may be arranged in the vertical direction (the z-axis direction).

The 2D image obtained by the plasma detector 130 may include a plurality of pixels having the same arrangement as the 2D pixel array. In other words, the 2D image obtained by the plasma detector 130 may also include a plurality of pixels arranged in n1 rows and n2 columns. Pixel values of the plurality of pixels in the 2D image may be respectively proportional to values of light quantities of the plasma emission light sensed at the plurality of pixels in the 2D pixel array.

For example, the plasma detector 130 may include a photoelectric multiplier tube (PMT), a charge-coupled device (CCD) image sensor, or a complementary metal-oxide-semiconductor (CMOS) image sensor. However, the plasma detector 130 is not limited to the above-described devices, and it will be understood that the plasma detector 130 may also be implemented in various other types of devices capable of collecting the plurality of rays of plasma emission light and converting the light quantities of the collected emission light into electrical signals and outputting the same.

The controller 140 may be operatively coupled to the plasma detector 130. The controller 140 may include at least one of a microprocessor, a digital signal processor, and processing devices similar thereto.

The controller 140 may estimate a 3D spatial distribution of the plurality of rays of plasma emission light within the plasma space of interest SI on the basis of the 2D image obtained from the plasma detector 130 and a weight matrix W. Specifically, the controller 140 may obtain a 3D spatial distribution vector f of the plurality of rays of plasma emission light by multiplying an image vector g, which includes pixel values of the plurality of respective pixels in the 2D image, by an inverse matrix W⁻¹ of the weight matrix W.

In some implementations, the weight matrix W may represent a matrix that shows the relationship between the plurality of voxels in the plasma space of interest SI and the plurality of pixels in the 2D pixel array. The weight matrix W may include a plurality of weight coefficients that respectively represent correlations between the plurality of voxels in the plasma space of interest SI and the plurality of pixels in the 2D pixel array.

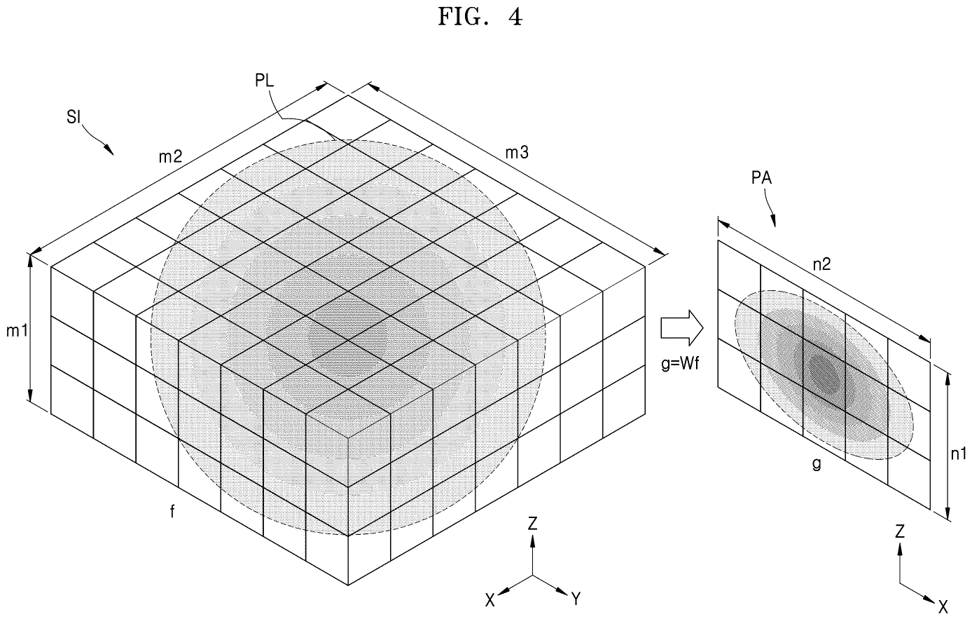

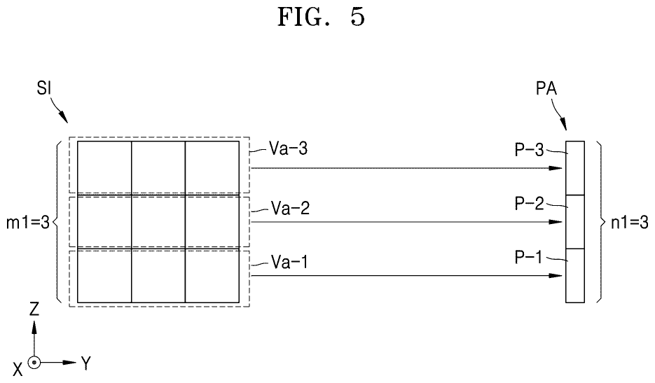

For example, when the plasma space of interest SI includes a plurality of M voxels and the 2D pixel array includes a plurality of N pixels, the 3D spatial distribution vector f may have a vector with M components and the 2D image vector g may have a vector with N components. In this case, the weight matrix W may be implemented as a matrix of size N*M. In other words, the weight matrix W may include a matrix with N*M weight coefficients. The N*M weight coefficients may have values respectively representing correlations between the M voxels and the N pixels. The image vector g, the 3D spatial distribution vector f, and the weight matrix W are described below in detail with reference to FIGS. 4 and 5.

The viewport 200 may be located in the sidewall of the plasma chamber housing 300. The viewport 200 may include an optical window for allowing optical access to the plasma space of interest SI. The viewport 200 may include materials, such as glass, quartz, fused silica, and sapphire. The plurality of rays of plasma emission light emitted from the plasma PL present in the plasma space of interest SI may be input to the plasma monitoring unit 10 via the viewport 200.

The plasma chamber housing 300 may define a plasma formation space and seal the plasma formation space from the outside. Generally, the plasma chamber housing 300 may include a metallic material and be connected to a ground potential. The plasma chamber housing 300 may be connected to the ground potential and thus block noise from the outside during a plasma process. An insulating liner may be located inside the plasma chamber housing 300, and the insulating liner may protect the plasma chamber housing 300 and cover metal structures protruding from the plasma chamber housing 300 to thereby prevent arcing or the like. The insulating liner may include ceramic, quartz, or the like.

The upper electrode 310 may be provided inside the plasma chamber housing 300 and disposed above the plasma formation space. The upper electrode 310 may receive radio frequency (RF) power from an external RF circuit. Also, the upper electrode 310 may be coupled to a ground potential.

Also, the upper electrode 310 may spray gas toward the plasma formation space. The gas may represent any gas required by the plasma process, such as, a source gas, a reaction gas, a purge gas, and an etch gas. The upper electrode 310 may also be referred to as various other names such as, a shower head, an upper plate, and an upper discharge plate.

The lower electrode 320 may be provided inside the plasma chamber housing 300 and disposed below the plasma formation space. The lower electrode 320 may receive RF power and bias potential from an external RF circuit.

An object to be processed by the plasma process, i.e., a wafer, may be disposed on the upper surface of the lower electrode 320. The lower electrode 320 may hold the wafer on the basis of electrostatic force.

The lower electrode 320 may also be referred to as various other names such as, an electrostatic chuck (ESC), a lower plate, and a lower discharge plate.

The plasma monitoring apparatus 1000 may include components as described above and thus accurately estimate the 3D spatial distribution of the plurality of rays of plasma emission light emitted from the plasma PL formed inside the plasma space of interest SI. In particular, due to the configuration of the lens unit in the plasma monitoring apparatus 1000, the plurality of rays of vertical emission light vl1 respectively emitted from the plurality of vertical levels inside the plasma space of interest SI may travel in directions parallel to each other and arrive at the detection surface of the plasma detector 130. Accordingly, a condition number of the weight matrix W may be small, and a 3D spatial distribution reconstruction operation of the plasma emission light by the controller 140 may be insensitive to disturbances.

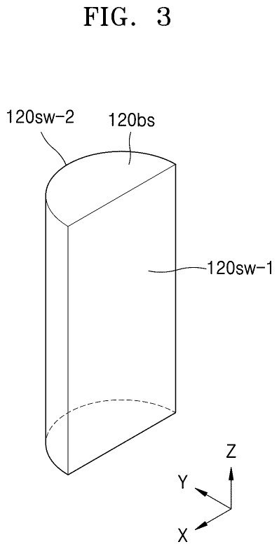

FIG. 3 is a perspective view of an example of the cylindrical lens 120.

Referring to FIG. 3, the cylindrical lens 120 may include a base 120bs, a first side surface 120sw-1, and a second side surface 120sw-2.

The first side surface 120sw-1 may face the viewport 200. The first side surface 120sw-1 may include a surface to which the plurality of rays of plasma emission light is input. In some implementations, the first side surface 120sw-1 may have a rectangular shape as shown in FIG. 3.

In some implementations, the first side surface 120sw-1 may have a circumferential surface shape. That is, the first side surface 120sw-1 may have a circumferential surface shape that is convex in an opposite direction (a −Y direction) to the second horizontal direction. In this case, a radius of curvature of the first side surface 120sw-1 may be greater than a radius of curvature of the second side surface 120sw-2. That is, the degree of convexity of the first side surface 120sw-1 may be less than the degree of convexity of the second side surface 120sw-2.

However, the shape of the first side surface 120sw-1 is not limited to the examples described above, and may be implemented in various shapes capable of receiving plasma emission light having a wide FOV in the first horizontal direction.

The second side surface 120sw-2 may face the plasma detector 130. Also, the second side surface 120sw-2 may be oriented perpendicular to the horizontal direction. In some implementations, as shown in FIG. 3, the second side surface 120sw-2 may have a circumferential surface shape that is convex in the second horizontal direction.

The base 120bs may represent each of an upper surface and a lower surface of the cylindrical lens 120. The base 120bs may have a planar shape, and the base 120bs may be connected and fixed to the monitoring structure 110. The shape of the base 120bs may be determined based on the shape of the first side surface 120sw-1 and the shape of the second side surface 120sw-2.

In some implementations, when the first side surface 120sw-1 has a rectangular shape and the second side surface 120sw-2 has a circumferential surface shape, the base 120bs may have the shape of a circular segment surrounded by an arc and a chord, as shown in FIG. 3. Here, when the central angle of the arc constituting the circular segment is 180 degrees, the base 120bs may have a semicircular shape.

In some implementations, when the first side surface 120sw-1 has a circumferential surface shape that is convex in the opposite direction (the −Y direction) to the second horizontal direction and the second side surface 120sw-2 has a circumferential surface shape that is convex in the second horizontal direction (the +Y direction), the base 120bs may have a shape in which two circular segments are coupled to each other.

In addition, the shape of the base 120bs is not limited to the examples described above and may be, for example, a shape in which a circular segment and a rectangle are coupled to each other. The base 120bs may have various other shapes, such as having a convex shape in the second horizontal direction and a flat planar shape (not concave or convex) in the vertical direction.

As shown in FIG. 3, the cylindrical lens 120 has a shape that is neither concave nor convex in the vertical direction and may thus have the identical cross-sections (i.e., cross-sections parallel to the xy plane) at all vertical levels. That is, the cylindrical lens 120 may have geometric uniformity in the vertical direction.

As described above, the cylindrical lens 120 may include the second side surface 120sw-2 convex in the second horizontal direction to collect the plurality of rays of plasma emission light in the first horizontal direction and may have geometric uniformity in the vertical direction to transmit the plurality of rays of plasma emission light without refraction.

In some implementations, the cylindrical lens 120 may include a second side surface 120sw-2 that is concave in the second horizontal direction. In this case, the cylindrical lens 120 may be formed as a plurality of lenses.

For example, the cylindrical lens 120 may include a first cylindrical lens and a second cylindrical lens that are arranged in series. The first cylindrical lens located relatively at the front end may have a side surface convex in the second horizontal direction and a side surface convex in the opposite direction to the second horizontal direction. In other words, the first cylindrical lens may include a lens that has the shape of a convex lens in a top-view. The second cylindrical lens located behind the first cylindrical lens may have a side surface concave in the second horizontal direction and a side surface concave in the opposite direction to the second horizontal direction. In other words, the second cylindrical lens may include a lens that has the shape of a concave lens in a top-view.

In the top-view, the cylindrical lens 120 may include the first cylindrical lens having the shape of the convex lens and the second cylindrical lens having the shape of the concave lens and arranged in series behind the first cylindrical lens, thereby collimating the plasma emission light in a wide FOV in the first horizontal direction and telecentrically transmitting the plasma emission light in the vertical direction.

In addition to the examples described above, the cylindrical lens 120 may be implemented as lenses having various numbers and various other types of arrangement configurations that are capable of collimating the plasma emission light in the wide FOV in the first horizontal direction and telecentrically transmitting the plasma emission light in the vertical direction.

FIG. 4 is a perspective view schematically illustrating an example of a method of estimating the 3D spatial distribution of the plasma emission light in the plasma monitoring apparatus 1000.

Referring to FIG. 4, a plasma space of interest SI may include a plurality of voxels arranged in a three-dimensional arrangement, and a 2D pixel array PA of the plasma detector 130 may include a plurality of pixels arranged in a two-dimensional arrangement.

In some implementations, the plasma space of interest SI may include a plurality of voxels that are arranged in a three-dimensional arrangement having m1 layers, m2 rows, and m3 columns. Here, each of the plurality of voxels may have a cuboid shape. In addition, the 2D pixel array PA may include a plurality of pixels that are configured in n1 rows and n2 columns. Here, each of the plurality of pixels may have a rectangular shape.

An image vector g represents a vector that has, as components, respective pixel values (e.g., grayscale values) for a plurality of pixels in the 2D pixel array PA. For example, when the 2D pixel array PA includes 15 pixels, the image vector g may represent a vector including (g₁=212, g₂=255, . . . , and g₁₅=23).

A 3D spatial distribution vector f may represent a vector that has, as components, respective irradiance values of plasma emission light of the plurality of voxels in the plasma space of interest SI. For example, when the plasma space of interest SI includes 7*7*3 voxels, the 3D spatial distribution vector f may represent a vector including (f₁=300, f₂=225, . . . , and f₁₄₇=280).

The weight matrix W may include a plurality of weight coefficients that respectively represent correlations between the plurality of voxels in the plasma space of interest SI and the plurality of pixels in the 2D pixel array PA. The plurality of weight coefficients may each have a value from about 0 to about 1, and the number of weight coefficients may be equal to the product of the number of components of the image vector g and the number of components of the 3D spatial distribution vector f. For example, when the 2D pixel array PA includes 15 pixels and the plasma space of interest SI includes 7*7*3 voxels, the number of weight coefficients may be 2205.

Here, the correlations between the plurality of voxels and the plurality of pixels may be determined on the basis of view frustums of the plurality of respective pixels in the 2D pixel array PA. Also, the view frustum of each of the plurality of pixels may be determined on the basis of the configuration and arrangement of a lens unit of the plasma monitoring apparatus 1000.

For example, it may be assumed that a view frustum of a first pixel in the 2D pixel array PA includes a first voxel and a second voxel. In this case, when the view frustum of the first pixel includes entirely the volume of the first voxel, the correlation between the first pixel and the first voxel may be “1,” and the weight coefficient representing the correlation between the first pixel and the first voxel may also have a value of “1.” On the other hand, when the view frustum of the first pixel includes only 30% of the volume of the second voxel, the correlation between the first pixel and the second voxel may be “0.3,” and the weight coefficient representing the correlation between the first pixel and the second voxel may have a value of “0.3.” On the other hand, all of the plurality of voxels that are not within the view frustum of the first pixel have a correlation of “0,” and thus all of the plurality of weight coefficients representing the correlations of the plurality of voxels that are not within the view frustum of the first pixel may have a value of “0.”

According to the configuration and arrangement of the lens unit of the plasma monitoring apparatus 1000, the weight matrix W may include the plurality of weight coefficients that respectively associate the plurality of vertical levels in the plasma space of interest SI with the n1 rows in the 2D pixel array PA in a one-to-one correspondence.

Specifically, referring back to FIG. 1, the cylindrical lens 120 may telecentrically transmit the plurality of rays of plasma emission light in the vertical direction. Therefore, plasma emission light emitted from the uppermost vertical level of the plasma space of interest SI may only arrive at pixels in any one row of the 2D pixel array PA, and plasma emission light emitted from the lowermost vertical level of the plasma space of interest SI may only arrive at pixels in another row of the 2D pixel array PA.

Therefore, according to the configuration and arrangement of the lens unit as shown in FIG. 1, the view frustum of each of the plurality of pixels in the 2D pixel array PA may include only voxels arranged at the same vertical level as the respective pixel, and may not include voxels arranged at vertical levels different therefrom.

As described above, the plurality of vertical levels in the plasma space of interest SI may be associated, in a one-to-one correspondence, with the n1 rows in the 2D pixel array PA, and thus, the effect may be achieved that the plasma space of interest SI may be divided into voxels in a three-dimensional arrangement including a large number of layers. This is described below in detail in the description with reference to FIG. 5.

FIG. 4 shows that the plasma space of interest SI includes 7*7*3 voxels, but this is only an example. The plasma space of interest SI may include any number of voxels. Also, it is illustrated that the 2D pixel array PA includes 3*5 pixels, but this is only an example. The 2D pixel array may include any number of pixels.

FIG. 5 is an example schematic cross-sectional view of a plurality of voxels and a 2D pixel array.

Referring to FIG. 5, the plasma space of interest SI may include a first layer-voxel array Va-1, a second layer-voxel array Va-2, and a third layer-voxel array Va-3. Also, the 2D pixel array PA may include first row-pixels P-1, second row-pixels P-2, and third row-pixels P-3.

In the description with reference to FIG. 5, it is illustrated that the plasma space of interest SI includes a plurality of voxels arranged in 3 layers, m2 rows, and m3 columns. Also, it is illustrated that the 2D pixel array PA includes a plurality of pixels arranged in 3 rows and n2 columns.

The first layer-voxel array Va-1, the second layer-voxel array Va-2, and the third layer-voxel array Va-3 may each include m2*m3 voxels. Also, the first row-pixels P-1, the second row-pixels P-2, and the third row-pixels P-3 may each include n2 pixels.

According to the configuration and arrangement of the lens unit of the plasma monitoring apparatus 1000, a plurality of rays of plasma emission light emitted from the first layer-voxel array Va-1 may arrive only at the first row-pixels P-1, a plurality of rays of plasma emission light emitted from the second layer-voxel array Va-2 may arrive only at the second row-pixels P-2, and a plurality of rays of plasma emission light emitted from the third layer-voxel array Va-3 may arrive only at the third row-pixels P-3.

In general, each of the plurality of pixels in the 2D pixel array PA may have a vertical height of about 1 μm to about 100 μm. On the other hand, when the plasma space of interest SI is divided into virtual voxels to estimate the 3D spatial distribution, the vertical height of each of the plurality of voxels may be several millimeters to tens of millimeters.

In this case, when the lens unit of the plasma monitoring apparatus 1000 does not telecentrically transmit a plurality of rays of plasma emission light in the vertical direction, but rather collects a plurality of rays of plasma emission light even in the vertical direction and transmit the same, rays of plasma emission light emitted from a plurality of layers of voxel arrays may arrive at pixels in a single row while overlapping each other. Accordingly, the pixels in the single row detect the overlapping rays of plasma emission light emitted from the plurality of layers of voxel arrays, and an accurate 3D spatial distribution may not be reconstructed.

On the other hand, since the lens unit of the plasma monitoring apparatus 1000 telecentrically transmits a plurality of rays of plasma emission light in the vertical direction, rays of the plasma emission light emitted from each of a plurality of layers of voxel arrays do not arrive at pixels in a single row while overlapping each other. Also, according to the configuration and arrangement of the lens unit of the plasma monitoring apparatus 1000 as illustrated in FIG. 1, the vertical height of each of the plurality of voxels may be set equal to the vertical height of each of the plurality of pixels.

For example, when each of the plurality of pixels in the 2D pixel array PA has a vertical height of 100 μm, the vertical height of each of the plurality of voxels may also be set to 100 μm. Accordingly, the plasma space of interest SI may be divided into a large number of layers.

Referring back to FIG. 4, according to the configuration described above, the weight matrix W may include a plurality of weight coefficients that respectively associate the m2*m3 voxels in the m1 layers with the n2 pixels in the n1 rows. For example, the weight matrix W may include m2*m3*n2 weight coefficients for associating m2*m3 voxels in a first layer with n2 pixels in a first row, include m2*m3*n2 weight coefficients for associating m2*m3 voxels in a second layer with n2 pixels in a second row, and include m2*m3*n2 weight coefficients for associating m2*m3 voxels in a third layer with n2 pixels in a third row.

The weight matrix W includes a plurality of weight coefficients as components of the matrix as described above, and thus, the condition number of the weight matrix W may decrease. Here, the term “the condition number of the weight matrix W” may represent an error rate in numerical computation that inevitably occurs when performing matrix operations. Specifically, in a linear equation “g=Wf” shown in FIG. 4, the 3D spatial distribution vector f represents a solution to the linear equation, and the image vector g represents an input to the linear equation. The “condition number of the weight matrix W” may represent a ratio of a relative error of the solution to a relative error of the input. That is, “the condition number of the weight matrix W increases” may indicate that “the ratio of the relative error of the solution to the relative error of the input increases (the linear equation is ill-posed, and the sensitivity of the linear equation increases).” Conversely, “the condition number of the weight matrix W decreases” may indicate that “the ratio of the relative error of the solution to the relative error of the input decreases (the linear equation is relatively well-posed, and the sensitivity of the linear equation relatively decreases).”

Specifically, based on the configuration and arrangement of the lens unit of the plasma monitoring apparatus 1000, rays of plasma emission light emitted from each of the plurality of vertical levels within the plasma space of interest SI arrive at pixels in the same row of the 2D pixel array PA without overlapping each other. Accordingly, the weight matrix W having a reduced condition number may be formed. Accordingly, based on the image vector g and the weight matrix W having a reduced condition number, the plasma monitoring apparatus 1000 may accurately obtain the 3D spatial distribution vector f, which is a solution of the linear equation “g=Wf.”

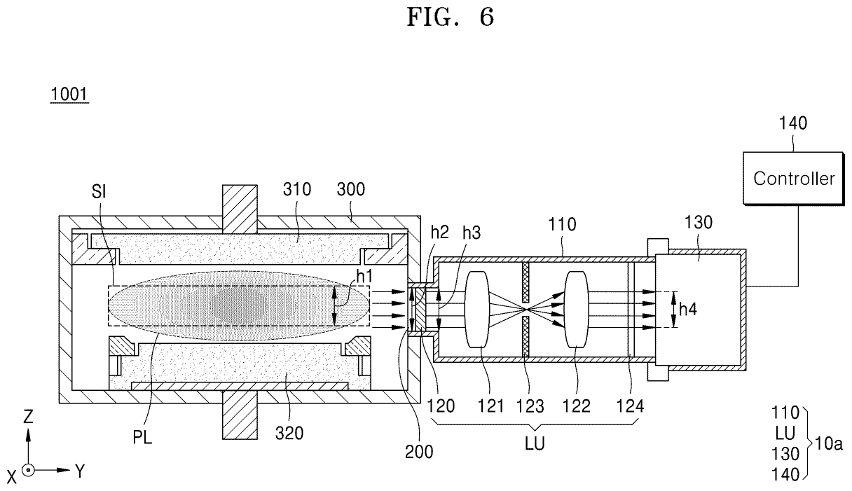

FIG. 6 is a cross-sectional view of an example of a plasma monitoring apparatus 1001.

When describing the plasma monitoring apparatus 1001 of FIG. 6, repeated descriptions as the plasma monitoring apparatus 1000 given with reference to FIGS. 1 and 2 are omitted, and the detailed description focuses on differences from the plasma monitoring apparatus 1000 of FIGS. 1 and 2.

A lens unit LU of the plasma monitoring apparatus 1001 may further include the cylindrical lens 120, a first circular lens 121, a second circular lens 122, the aperture 123, and the optical filter 124.

The first circular lens 121 and the second circular lens 122 are provided inside the monitoring structure 110 and arranged behind the cylindrical lens 120, and may collect a plurality of rays of plasma emission light that have transmitted through the cylindrical lens 120.

Unlike the cylindrical lens 120 that transmits light telecentrically in the vertical direction and collimates light in the first horizontal direction, the first circular lens 121 and the second circular lens 122 may collect light in both the vertical direction and the first horizontal direction. The first circular lens 121 and the second circular lens 122 may collect, by a preset magnification, the plurality of rays of plasma emission light that have transmitted through the cylindrical lens 120.

The preset magnification may be determined based on the size of a 2D pixel array PA in the plasma detector 130. For example, it is assumed that the 2D pixel array PA has a height of “h4” in the vertical direction and a width of “w3” in the first horizontal direction. In this case, the preset magnification in the vertical direction may be determined based on “h4” that is the height of the 2D pixel array PA in the vertical direction and “h3” that is the height of the cylindrical lens 120 in the vertical direction. For example, the preset magnification in the vertical direction may be

$$“ \frac{h 4}{h 3} . ”$$

Referring back to FIG. 2, the preset magnification in the first horizontal direction may be determined based on “w2” that is the width of the cylindrical lens 120 in the first horizontal direction and “w3” that is the width of the 2D pixel array PA in the first horizontal direction. For example, the preset magnification in the first horizontal direction may be

$$“ \frac{w 3}{w 2} . ”$$

As described above, the preset magnification may be determined based on both the size of the cylindrical lens 120 and the size of the 2D pixel array PA. The ratio of the focal lengths of the first circular lens 121 and the second circular lens 122 may be determined based on the preset magnification described above. For example, when the preset magnification is

$$“ \frac{w 3}{w 2} ” ,$$

a ratio of a focal length (f1) of the first circular lens 121 and a focal length (f2) of the second circular lens 122 may also be determined to be

$$“ \frac{w 3}{w 2} ” ( \frac{w 3}{w 2} = \frac{f 2}{f 1} ) .$$

The first circular lens 121 and the second circular lens 122 may each have an outer surface that is convex in both the vertical direction and the horizontal direction. For example, the first circular lens 121 and the second circular lens 122 may have a spherically symmetric structure.

The aperture 123 may be located between the first circular lens 121 and the second circular lens 122. Specifically, the aperture 123 may function to ensure that only the plurality of rays of plasma emission light are transmitted toward the plasma detector 130. In other words, the aperture 123 may block the transmission of unnecessary light. The unnecessary light may include external light, plasma emission light at a certain angle and in a certain direction, or the like. Specifically, the aperture 123 may allow transmission of only a plurality of rays of plasma emission light, traveling parallel to the vertical direction and the second horizontal direction, among rays of light that have transmitted through the cylindrical lens 120, but may block all rays of light traveling in other directions and at other angles.

The aperture 123 may include a quadrangular hole having a width and a length of 1 mm or less. In addition, the aperture 123 may be located at a position spaced rearward from the first circular lens 121 by the focal length (f1) of the first circular lens 121 and located at a position spaced forward from the second circular lens 122 by the focal length (f2) of the second circular lens 122.

FIG. 6 shows that the lens unit LU includes two circular lenses, but this is only an example. At least two circular lenses or only one circular lens may be used to collect the plurality of rays of plasma emission light at the preset magnification. Also, as the number of apertures 123 increases, the number of circular lenses may correspondingly increase.

The optical filter 124 may be located in front of the plasma detector 130. The optical filter 124 may allow transmission of only a plurality of rays of plasma emission light but block rays of other light. For example, the optical filter 124 may block electrode surface emission light. The optical filter 124 may be formed as a band wavelength filter that passes only light in a specific wavelength range, a polarization filter that passes only light in a specific polarization direction, or the like.

As described above, a plasma monitoring unit 10a of the plasma monitoring apparatus 1001 may further include at least one circular lens, the aperture 123, and the optical filter 124. Accordingly, the plurality of rays of plasma emission light emitted from the plasma space of interest SI may be accurately transmitted to the plasma detector 130 in an intended direction and at an intended angle.

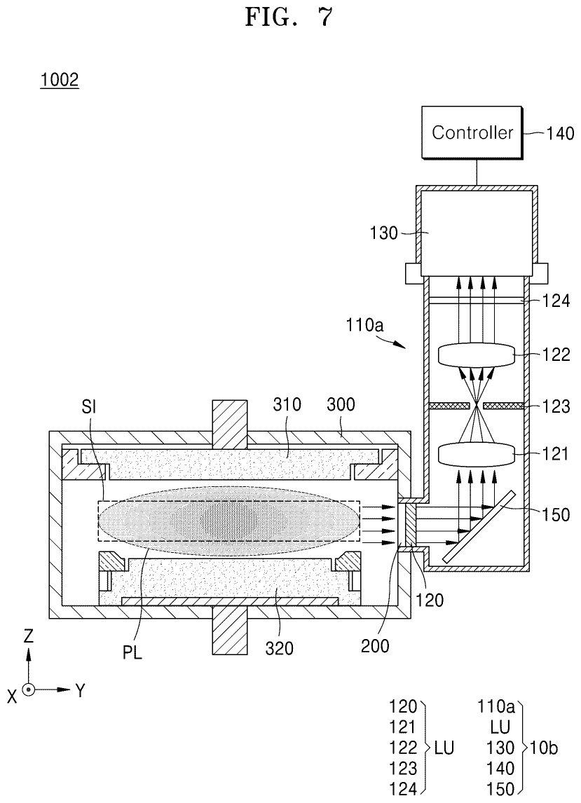

FIG. 7 is a cross-sectional view of an example of a plasma monitoring apparatus 1002.

When describing the plasma monitoring apparatus 1002 of FIG. 7, repeated descriptions as the plasma monitoring apparatuses 1000 and 1001 given with reference to FIGS. 1 and 2 and FIG. 6, respectively, are omitted, and the detailed description focuses on differences therebetween.

A plasma monitoring unit 10b of the plasma monitoring apparatus 1002 may include a monitoring structure 110a and a mirror 150.

The monitoring structure 110a may constitute the exterior of the plasma monitoring unit 10b. The monitoring structure 110a may have an “L” shape and include a certain inner space. Specifically, the monitoring structure 110a may include a horizontal portion, which is in contact with the viewport 200 and fixed to a sidewall of the plasma chamber housing 300, and a vertical portion, which is connected to the horizontal portion and extends perpendicular to the horizontal portion.

The cylindrical lens 120 may be located inside the horizontal portion. Also, the first circular lens 121, the second circular lens 122, the aperture 123, the optical filter 124, and the plasma detector 130 may be arranged inside the vertical portion.

FIG. 7 illustrates only that the vertical portion of the monitoring structure 110a extends upward in the vertical direction, but the vertical portion of the monitoring structure 110a may also extend downward in the vertical direction. Also, the vertical portion of the monitoring structure 110a may extend in the first horizontal direction (the +X direction) or in the opposite direction (the −X direction) of the first horizontal direction.

The mirror 150 may deliver, to the plasma detector 130, a plurality of rays of plasma emission light that have transmitted through the cylindrical lens 120. The mirror 150 may be located at an intersection point at which the horizontal portion of the monitoring structure 110a intersects the vertical portion of the monitoring structure 110a. Specifically, as shown in FIG. 7, when the vertical portion of the monitoring structure 110a extends upward in the vertical direction, the mirror 150 may be located at the intersection point while inclined at 45 degrees relative to the vertical direction.

As described above, the plasma monitoring unit 10b of the plasma monitoring apparatus 1002 may further include the monitoring structure 110a having the “L” shape and the mirror 150 located at the intersection point of the monitoring structure 110a. Accordingly, the horizontal space in which the plasma monitoring apparatus 1002 is placed may be saved, and the vertical space may be utilized more efficiently. In addition, the plasma monitoring unit 10b may be located relatively adjacent to the side of the plasma chamber housing 300, which may improve structural stability.

Referring to FIGS. 1 to 7, it is shown that one plasma monitoring unit 10 may be fixed to the sidewall of the plasma chamber housing 300, but this is only an example. Two or more plasma monitoring units 10 may be fixed to the sidewalls of the plasma chamber housing 300. When two or more plasma monitoring units 10 are fixed to the sidewalls of the plasma chamber housing 300, the number of viewports 200 corresponding to the number of plasma monitoring units 10 may be arranged in the sidewalls of the plasma chamber housing 300.

In the above drawings and description, it is only illustrated that the plasma monitoring unit 10 according to one or more implementations may be arranged in the sidewalls of a capacitively coupled plasma (CCP) chamber housing provided with the upper electrode 310 and the lower electrode 320. However, this is only an example, and the plasma monitoring unit 10 may be coupled to sidewalls of various types of chamber housings which include viewports 200 in the sidewalls and form plasma PL in the inner spaces thereof.

For example, the plasma monitoring unit 10 may be coupled to the sidewall of an inductively coupled plasma (ICP) chamber housing. Alternatively, the plasma monitoring unit 10 may be coupled to the sidewall of an electron cyclotron resonance (ECR) plasma chamber housing or the like. That is, the plasma monitoring unit 10 may be coupled to the sidewalls of various types of plasma chamber housings 300.

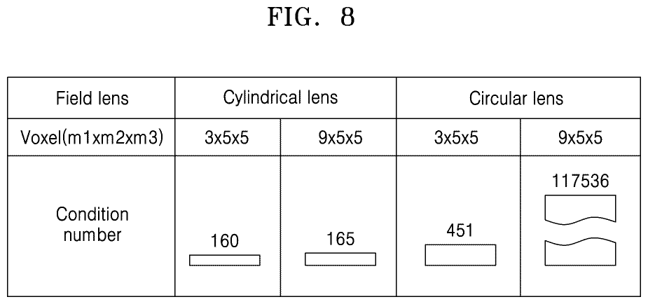

FIG. 8 is a table schematically showing the effect of an example of a plasma monitoring apparatus.

FIG. 8 is a table showing condition numbers of weight matrices W in the case of using a cylindrical lens as a field lens and the case of using a circular lens as a field lens, which have been verified through optical simulations. Here, the field lens may represent a lens that is located at the front end of the monitoring structure 110. For example, referring to FIG. 1, the field lens may represent the cylindrical lens 120.

Referring to the table in FIG. 8, when the cylindrical lens is used as the field lens, it can be seen that the condition number of the weight matrix W is 160 when the plasma space of interest SI is divided into 3 layers, 5 rows, and 5 columns. Also, under the same conditions of using the cylindrical lens as the field lens, it can be seen that the condition number of the weight matrix W is 165 when the plasma space of interest SI is divided into 9 layers, 5 rows, and 5 columns.

That is, the cylindrical lens telecentrically transmits the plurality of rays of plasma emission light in the vertical direction. Therefore, when the cylindrical lens is used as the field lens, the condition number of the weight matrix W may have a constant value irrespective of the number of vertical levels of the plasma space of interest SI.

Also, the condition number of the weight matrix W when the cylindrical lens is used as the field lens may be less than the condition number of the weight matrix W when the circular lens is used as the field lens.

Referring to the table in FIG. 8, when the circular lens is used as the field lens, it can be seen that the condition number of the weight matrix W is 451 when the plasma space of interest SI is divided into 3 layers, 5 rows, and 5 columns. Also, under the same conditions of using the circular lens as the field lens, it can be seen that the condition number of the weight matrix W is 117,536 when the plasma space of interest SI is divided into 9 layers, 5 rows, and 5 columns.

That is, the condition number of the weight matrix W when the circular lens is used as the field lens may be much greater than the condition number of the weight matrix W when the cylindrical lens is used as the field lens. Also, when the circular lens is used as the field lens, it can be seen that the condition number of the weight matrix W increases exponentially as the vertical levels of the plasma space of interest SI are divided into a larger number of layers.

Therefore, the plasma monitoring apparatus may include the cylindrical lens as the field lens and thus reconstruct the 3D spatial distribution of the plasma emission light on the basis of the weight matrix W having a small condition number. Also, the plasma monitoring apparatus may divide the vertical levels of the plasma space of interest SI into a very large number of layers and thus reconstruct the spatial distribution in the vertical direction more precisely.

As described above, the plasma monitoring apparatus may achieve the effect of being able to accurately reconstruct the 3D spatial distribution of the plurality of rays of plasma emission light emitted from the plasma space of interest SI without being sensitive to disturbances.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A plasma monitoring apparatus comprising:
a monitoring structure at a sidewall of a plasma chamber housing, wherein the monitoring structure contacts a viewport located at the sidewall of the plasma chamber housing;
a cylindrical lens located at a front end of the monitoring structure, the cylindrical lens being configured to receive a plurality of rays of plasma emission light, the plurality of rays of plasma emission light being emitted from a plasma space of interest inside the plasma chamber housing; and
a plasma detector located at a rear end of the monitoring structure, the plasma detector being configured to detect the plurality of rays of plasma emission light, the plurality of rays of plasma emission light being transmitted through the cylindrical lens,
wherein the cylindrical lens comprises a side surface, the side surface having a circumferential surface convex or concave in a horizontal direction,
wherein the side surface of the cylindrical lens faces the plasma detector and is oriented perpendicular to the horizontal direction,
wherein the plasma space of interest comprises a space in an inner space of the plasma chamber housing, the space and the viewport having a same vertical level, and
wherein the horizontal direction is defined from a center of the plasma space of interest toward the viewport.

2. The plasma monitoring apparatus of claim 1, wherein the cylindrical lens is configured to collimate a plurality of rays of horizontal emission light among the plurality of rays of plasma emission light, the plurality of rays of horizontal emission light being emitted from a plurality of identical vertical spaces, and
wherein each vertical space of the plurality of identical vertical spaces comprises a plurality of voxels having a same vertical coordinate within the plasma space of interest.

3. The plasma monitoring apparatus of claim 2, wherein a plurality of horizontal light paths incident to the cylindrical lens are inclined at different angles relative to the horizontal direction, and
wherein the plurality of rays of horizontal emission light are incident to the cylindrical lens along a plurality of light paths, the plurality of light paths respectively corresponding to the plurality of horizontal light paths.

4. The plasma monitoring apparatus of claim 1, wherein the cylindrical lens is configured to pass, without refraction, a plurality of rays of vertical emission light among the plurality of rays of plasma emission light, the plurality of rays of vertical emission light being emitted from a plurality of identical horizontal spaces, and
wherein each vertical space of the plurality of identical horizontal spaces comprises a plurality of voxels having a same horizontal coordinate within the plasma space of interest.

5. The plasma monitoring apparatus of claim 4, wherein a plurality of vertical light paths incident to the cylindrical lens are parallel to the horizontal direction, and
wherein the plurality of rays of vertical emission light are incident to the cylindrical lens along a plurality of light paths, the plurality of light paths respectively corresponding to the plurality of vertical light paths.

6. The plasma monitoring apparatus of claim 1, wherein a vertical thickness of the cylindrical lens is equal to a vertical height of the plasma space of interest.

7. The plasma monitoring apparatus of claim 1, comprising a controller configured to estimate, based on a weight matrix and a 2D image, a 3D spatial distribution of the plurality of rays of plasma emission light within the plasma space of interest, the weight matrix and the 2D image being obtained from the plasma detector,
wherein the plasma detector comprises a 2D pixel array configured to receive the plurality of rays of plasma emission light.

8. The plasma monitoring apparatus of claim 7, wherein the 2D pixel array comprises a plurality of pixels, the plurality of pixels being positioned in a two-dimensional arrangement having n1 rows and n2 columns, n1 and n2 being two natural numbers greater than or equal to 2, and
wherein the weight matrix comprises a first plurality of weight coefficients, the first plurality of weight coefficients respectively associating a plurality of vertical levels in the plasma space of interest with the n1 rows in a one-to-one correspondence.

9. The plasma monitoring apparatus of claim 8, wherein the plasma space of interest comprises a plurality of voxels, the plurality of voxels being positioned in a three-dimensional arrangement having m1 layers, m2 rows, and m3 columns, m1, m2, and m3 being three natural numbers greater than or equal to 2, and
wherein the weight matrix comprises a second plurality of weight coefficients, the second plurality of weight coefficients respectively associating m2*m3 voxels in the m1 layers with n2 pixels in the n1 rows.

10. The plasma monitoring apparatus of claim 1, wherein the plasma detector comprises a photoelectric multiplier tube, a charge-coupled device image sensor, or a complementary metal-oxide-semiconductor image sensor.

11. The plasma monitoring apparatus of claim 1, wherein a horizontal distance between the viewport and the side surface of the cylindrical lens is less than or equal to 10 mm.

12. A plasma monitoring apparatus comprising:
a monitoring structure at a sidewall of a plasma chamber housing, wherein the monitoring structure contacts a viewport located at the sidewall of the plasma chamber housing;
a lens located inside the monitoring structure and configured to
receive a plurality of rays of plasma emission light having a wide field of view,
output the received plurality of rays of plasma emission light in collimation in a first horizontal direction, and
output the received plurality of rays of plasma emission light telecentrically in a vertical direction;
a plasma detector configured to obtain, based on the plurality of rays of plasma emission light output from the lens, a 2D image; and
a controller configured to estimate, based on the 2D image and a weight matrix, a 3D spatial distribution of the plurality of rays of plasma emission light within a plasma space of interest,
wherein the 2D image comprises a plurality of pixels positioned in n1 rows and n2 columns, n1 and n2 being two natural numbers greater than or equal to 2,
wherein the weight matrix comprises a first plurality of weight coefficients, the first plurality of weight coefficients respectively associating a plurality of vertical levels in the plasma space of interest with the n1 rows in a one-to-one correspondence,
wherein the plasma space of interest comprises a space in an inner space of the plasma chamber housing, the space and the viewport having a same vertical level, and
wherein the first horizontal direction is perpendicular to a second horizontal direction, the second horizontal direction being from a center of the plasma space of interest toward the viewport.

13. The plasma monitoring apparatus of claim 12, wherein the lens comprises:
a cylindrical lens configured to
collimate the plurality of rays of plasma emission light in the first horizontal direction, and
transmit, without refraction, the plurality of rays of plasma emission light in the vertical direction; and
at least one circular lens located behind the cylindrical lens and configured to collect, in the first horizontal direction and the vertical direction, the plurality of rays of plasma emission light transmitted through the cylindrical lens.

14. The plasma monitoring apparatus of claim 13, wherein the plasma detector comprises a 2D pixel array configured to receive the plurality of rays of plasma emission light,
wherein the at least one circular lens is configured to collect the plurality of rays of plasma emission light in the first horizontal direction and the vertical direction so that the plurality of rays of plasma emission light are adjusted to a preset magnification, and
wherein the preset magnification is determined based on a size of the 2D pixel array.

15. The plasma monitoring apparatus of claim 13, wherein a vertical thickness of the cylindrical lens is equal to a vertical height of the plasma space of interest.

16. The plasma monitoring apparatus of claim 13, wherein a width of the cylindrical lens in the first horizontal direction is less than a width of the plasma space of interest in the first horizontal direction.

17. The plasma monitoring apparatus of claim 12, wherein the plasma space of interest comprises a plurality of voxels, the plurality of voxels being positioned in a three-dimensional arrangement having m1 layers, m2 rows, and m3 columns, m1, m2, and m3 being three natural numbers greater than or equal to 2, and
wherein the weight matrix comprises a second plurality of weight coefficients, the second plurality of weight coefficients respectively associating m2*m3 voxels in the m1 layers with n2 pixels in the n1 rows.

18. The plasma monitoring apparatus of claim 12, wherein the plasma detector comprises a photoelectric multiplier tube, a charge-coupled device image sensor, or a complementary metal-oxide-semiconductor image sensor.

19. A plasma monitoring apparatus comprising:
a plasma chamber housing;
a viewport located at a sidewall of the plasma chamber housing;
a monitoring structure contacting the viewport and at the sidewall of the plasma chamber housing;
at least one cylindrical lens located at a front end of the monitoring structure, the at least one cylindrical lens being configured to receive a plurality of rays of plasma emission light emitted from a plasma space of interest;
at least one circular lens located behind the at least one cylindrical lens, the at least one circular lens being configured to collect the plurality of rays of plasma emission light at a preset magnification; and
a plasma detector located behind the at least one circular lens, the plasma detector being configured to receive the plurality of rays of plasma emission light to obtain a 2D image,
wherein the at least one cylindrical lens is configured to receive the plurality of rays of plasma emission light having a wide field of view,
wherein the at least one cylindrical lens is configured to output the received plurality of rays of plasma emission light in collimation in a first horizontal direction and telecentrically in a vertical direction,
wherein the plasma space of interest comprises a space in an inner space of the plasma chamber housing, the space and the viewport having a same vertical level,
wherein the preset magnification is determined based on a size of a 2D pixel array in the plasma detector, and
wherein the first horizontal direction is perpendicular to a second horizontal direction, the second horizontal direction being from a center of the plasma space of interest toward the viewport.

20. The plasma monitoring apparatus of claim 19, comprising a controller configured to estimate, based on the 2D image and a weight matrix, a 3D spatial distribution of the plurality of rays of plasma emission light within the plasma space of interest,
wherein the plasma detector comprises a 2D pixel array configured to receive the plurality of rays of plasma emission light, the 2D pixel array comprising a plurality of pixels positioned in a two-dimensional arrangement having n1 rows and n2 columns, n1 and n2 being two natural numbers greater than or equal to 2, and
wherein the weight matrix comprises a plurality of weight coefficients, the plurality of weight coefficients respectively associating a plurality of vertical levels in the plasma space of interest with the n1 rows in a one-to-one correspondence.
